(19) United States
(12) Patent Application Publication
(10) Pub. No.: US 2019/0333850 A1
(43) Pub. Date: Oct. 31, 2019

(54) WIRING BOARD HAVING BRIDGING ELEMENT STRADDLING OVER INTERFACES

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 16/438,824

(22) Filed: Jun. 12, 2019

Related U.S. Application Data
(63) Continuation-in-part of application No. 15/369,896, filed on Dec. 6, 2016, now Pat. No. 10,361,151.
Application No. 15/369,896 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 14/846,987 is a continuation-in-part of application No. 15/080,427, filed on Mar. 24, 2016, now abandoned.
Application No. 15/080,427 is a continuation-in-part of application No. 14/846,987, filed on Sep. 7, 2015, now Pat. No. 10,420,204.
Application No. 14/846,987 is a continuation-in-part of application No. 14/621,332, filed on Feb. 12, 2015, now abandoned.
Application No. 14/846,987 is a continuation-in-part of application No. 14/621,332, filed on Feb. 12, 2015, now abandoned.
Application No. 14/621,332 is a continuation-in-part of application No. 15/881,119, filed on Jan. 26, 2018.
Application No. 15/881,119 is a continuation-in-part of application No. 15/605,920, filed on May 25, 2017, now abandoned.
(60) Provisional application No. 61/949,652, filed on Mar. 7, 2014.

(51) Int. Cl. H01L 23/498; H01L 23/367; H01L 23/00

(52) U.S. Cl. CPC H01L 23/49838; H01L 23/49827; H01L 23/564; H01L 23/3677

(57) ABSTRACT

A wiring board includes an electrical isolator or an interconnect element incorporated with a core substrate or metal leads and a bridging element straddling over interfaces between two adjoined surfaces to electrically connect a routing circuitry on the electrical isolator or on the interconnect element to another routing circuitry on the core substrate or to the metal leads. As the bridging element offers a reliable connecting channel without direct attachment to the interfaces, any cracking or delamination across the interfaces will not affect the routing integrity.

### CROSS REFERENCE TO RELATED APPLICATIONS

This application is a continuation-in-part of U.S. application Ser. No. 15/369,896 filed Dec. 6, 2016 and a continuation-in-part of U.S. application Ser. No. 15/881,119 filed Jan. 26, 2018.

The U.S. application Ser. No. 15/369,896 is a continuation-in-part of U.S. application Ser. No. 14/621,332 filed Feb. 12, 2015, a continuation-in-part of U.S. application Ser. No. 14/846,987 filed Sep. 7, 2015 and a continuation-in-part of U.S. application Ser. No. 15/080,427 filed Mar. 24, 2016. The U.S. application Ser. No. 15/881,119 is a continuation-in-part of U.S. application Ser. No. 15/605,920 filed May 25, 2017, a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/605,920 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 14/621,332 claims the priority benefit of U.S. Provisional Application Ser. No. 61/949,652 filed Mar. 7, 2014. The U.S. application Ser. No. 14/846,987 is a continuation-in-part of U.S. application Ser. No. 14/621,332 filed Feb. 12, 2015. The U.S. application Ser. No. 15/080,427 is a continuation-in-part of U.S. application Ser. No. 14/621,332 filed Feb. 12, 2015 and a continuation-in-part of U.S. application Ser. No. 14/846,987 filed Sep. 7, 2015. The entirety of each of said Applications is incorporated herein by reference.

### BACKGROUND OF THE INVENTION

### 1. Field of the Invention

The present invention relates to a wiring board and, more particularly, to a wiring board having a bridging element straddling over interfaces.

### 2. Description of Related Art

High performance microprocessors and ASICs require high performance wiring boards for signal interconnection. However, as the complexity of the board design increases, heterogeneous integration of a routing component may be needed to resolve many electrical or thermal related requirements. U.S. Pat. No. 8,859,908 to Wang et al., U.S. Pat. No. 8,415,780 to Sun, U.S. Pat. No. 9,185,791 to Wang and U.S. Pat. No. 9,706,639 to Lee disclose various package substrates in which a heat dissipation element is disposed in a through opening of a resin laminate so that the heat generated by semiconductor chip can be dissipated directly through the underneath heat dissipation element. However, as there is a significant coefficient of thermal expansion (CTE) mismatch between the heat dissipation element and the resin laminate, the contact areas are prone to crack. Therefore, these substrates are not suitable for interconnection usage if a portion of routing circuitries contact the interfacial boundaries directly.

In view of the various development stages and limitations in current substrates, improving substrate's electrical, thermal and mechanical performances is highly desirable.

### SUMMARY OF THE INVENTION

A primary objective of the present invention is to provide a wiring board with a heterogeneous routing component integrated therein. The wiring board is characterized by having a bridging element straddling over interfaces between two adjoined surfaces. The bridging element provides electrical route that bypasses the potentially interfacial cracking area caused by CTE mismatching.

Another objective of the present invention is to disperse stress modulators in an interfacial layer to form a modified matrix with a lower CTE. By adjusting the thermal-mechanical properties of the interfacial layer, the expansion and shrinkage of the interfacial layer can be alleviated, thereby improving the reliability of the bridging element that straddles thereover.

In accordance with the foregoing and other objectives, the present invention provides a wiring board, comprising: a core substrate having an aperture, wherein interior sidewalls of the aperture extend through the core substrate between a top surface and a bottom surface thereof; an electrical isolator disposed in the aperture of the core substrate, wherein the electrical isolator includes a plurality of heat conducting elements dispensed therein; a binding layer that fills a gap between peripheral sidewalls of the electrical isolator and the interior sidewalls of the aperture, wherein the binding layer has a coefficient of thermal expansion different from those of the electrical isolator and the core substrate; a first routing circuitry disposed on a top surface of the electrical isolator and a second routing circuitry disposed on the top surface of the core substrate, wherein the first routing circuitry and the second routing circuitry are substantially coplanar at exterior surfaces thereof and spaced apart from each other; and a bridging element that is attached to the first routing circuitry at one end and to the second routing circuitry at another end to electrically connect the first routing circuitry and the second routing circuitry, wherein no portion of the bridging element is directly attached to the top surface of the electrical isolator, the top surface of the core substrate or the binding layer between the electrical isolator and the core substrate.

In another aspect, the present invention provides another wiring board, comprising: a core substrate having an aperture, wherein interior sidewalls of the aperture extend through the core substrate between a top surface and a bottom surface thereof; an interconnect element disposed in the aperture of the core substrate, wherein the interconnect element includes a plurality of circuitry layers and a plurality of dielectric layers in an alternate fashion; a binding layer that fills a gap between peripheral sidewalls of the interconnect element and the interior sidewalls of the aperture, wherein the binding layer has a coefficient of thermal expansion different from those of the interconnect element and the core substrate; a first routing circuitry disposed on a top surface of the interconnect element and a second routing circuitry disposed on the top surface of the core substrate, wherein the first routing circuitry is electrically coupled to the circuitry layers of the interconnect element, and the first routing circuitry and the second routing circuitry are substantially coplanar at exterior surfaces thereof and spaced apart from each other; and a bridging element that is attached to the first routing circuitry at one end and to the second routing circuitry at another end to electrically connect the first routing circuitry and the second routing circuitry, wherein no portion of the bridging element is directly attached to the top surface of the interconnect element, the top surface of the core substrate or the binding layer between the interconnect element and the core substrate.

In yet another aspect, the present invention provides yet another wiring board, comprising: an interconnect element including a plurality of circuitry layers and a plurality of dielectric layers in an alternate fashion; a plurality of metal leads that laterally surround peripheral sidewalls of the interconnect element; a resin layer that fills spaces between the metal leads and surrounds the peripheral sidewalls of the interconnect element, wherein the resin layer has a coefficient of thermal expansion different from those of the interconnect element and the metal leads; a routing circuitry disposed on a top surface of the interconnect element, wherein the routing circuitry is electrically coupled to the circuitry layers of the interconnect element, and the routing circuitry and the metal leads are substantially coplanar at exterior surfaces thereof and spaced apart from each other; and a bridging element that is attached to routing circuitry at one end and to the plurality of metal leads at another end to electrically connect the routing circuitry and the plurality of metal leads, wherein no portion of the bridging element is directly attached to the top surface of the interconnect element or a top surface of the resin layer.

In yet another aspect, the present invention provides yet another wiring board, comprising: an electrical isolator including a plurality of heat conducting elements dispensed therein; a plurality of metal leads that laterally surround peripheral sidewalls of the electrical isolator; a resin layer that fills spaces between the metal leads and surrounds the peripheral sidewalls of the electrical isolator, wherein the resin layer has a coefficient of thermal expansion different from those of the electrical isolator and the metal leads; a routing circuitry disposed on a top surface of the electrical isolator, wherein the routing circuitry has an exterior surface substantially coplanar with top sides of the metal leads and is spaced apart from the metal leads; and a bridging element that is attached to routing circuitry at one end and to the plurality of metal leads at another end to electrically connect the routing circuitry and the plurality of metal leads, wherein no portion of the bridging element is directly attached to the top surface of the electrical isolator or a top surface of the resin layer.

These and other features and advantages of the present invention will be further described and more readily apparent from the detailed description of the preferred embodiments which follows.

### BRIEF DESCRIPTION OF THE DRAWINGS

The detailed description of the preferred embodiments of the present invention can best be understood when read in conjunction with the following drawings, in which:

FIG. 1 is a cross-sectional view of an electrical isolator provided with a top metal film and a bottom metal film in accordance with the first embodiment of the present invention;

FIGS. 2 and 3 are cross-sectional and top perspective views, respectively, of the structure of FIG. 1 formed with a first routing circuitry on the electrical isolator in accordance with the first embodiment of the present invention;

FIG. 4 is a cross-sectional view of a core substrate provided with a top metal layer and a bottom metal layer in accordance with the first embodiment of the present invention;

FIGS. 5 and 6 are cross-sectional and top perspective views, respectively, of the structure of FIG. 4 formed with a second routing circuitry on the core substrate in accordance with the first embodiment of the present invention;

FIG. 7 is a cross-sectional view of the structure of FIG. 5 further provided with an aperture in accordance with the first embodiment of the present invention;

FIGS. 8 and 9 are cross-sectional and top perspective views, respectively, of the structure of FIGS. 2 and 3 inserted into the aperture of the structure of FIG. 7 in accordance with the first embodiment of the present invention;

FIG. 10 is a cross-sectional view of the structure of FIG. 8 further provided with a modified binding matrix in accordance with the first embodiment of the present invention;

FIGS. 11 and 12 are cross-sectional and top perspective views, respectively, of the structure of FIG. 10 further provided with bridging elements to finish the fabrication of a wiring board in accordance with the first embodiment of the present invention;

FIGS. 13 and 14 are cross-sectional and top perspective views, respectively, of a semiconductor assembly with semiconductor devices mounted on the wiring board of FIGS. 11 and 12 in accordance with the first embodiment of the present invention;

FIG. 15 is a cross-sectional view of another aspect of the wiring board in accordance with the first embodiment of the present invention;

FIG. 16 is a cross-sectional view of yet another aspect of the wiring board in accordance with the first embodiment of the present invention;

FIG. 17 is a cross-sectional view of yet another aspect of the wiring board in accordance with the first embodiment of the present invention;

FIG. 18 is a cross-sectional view of yet another aspect of the wiring board in accordance with the first embodiment of the present invention;

FIGS. 19 and 20 are cross-sectional and top perspective views, respectively, of an electrical isolator provided with a first routing circuitry, a thermal pad and a bottom metal film in accordance with the second embodiment of the present invention;

FIGS. 21 and 22 are cross-sectional and top perspective views, respectively, of a core substrate provided with a second routing circuitry, a third routing circuitry and metallized through holes in accordance with the second embodiment of the present invention;

FIGS. 23 and 24 are cross-sectional and top perspective views, respectively, of the structure of FIGS. 19 and 20 inserted into an aperture of the structure of FIGS. 21 and 22 in accordance with the second embodiment of the present invention;

FIGS. 25 and 26 are cross-sectional and top perspective views, respectively, of the structure of FIGS. 23 and 24 further provided with a modified binding matrix in accordance with the second embodiment of the present invention;

FIGS. 27 and 28 are cross-sectional and top perspective views, respectively, of the structure of FIGS. 25 and 26 further provided with bridging elements to finish the fabrication of a wiring board in accordance with the second embodiment of the present invention;

FIGS. 29 and 30 are cross-sectional and top perspective views, respectively, of a semiconductor assembly with a semiconductor device and an electronic component mounted on the wiring board of FIGS. 27 and 28 in accordance with the second embodiment of the present invention;

FIG. 31 is a cross-sectional view of another aspect of the wiring board in accordance with the second embodiment of the present invention;

FIG. 32 is a cross-sectional view of yet another aspect of the wiring board in accordance with the second embodiment of the present invention;

FIG. 33 is a cross-sectional view of yet another aspect of the wiring board in accordance with the second embodiment of the present invention;

FIG. 34 is a cross-sectional view of an interconnect element provided with a first routing circuitry and a bottom metal film in accordance with the third embodiment of the present invention;

FIG. 35 is a cross-sectional view of a core substrate provided with a second routing circuitry, a third routing circuitry and metallized through holes in accordance with the third embodiment of the present invention;

FIG. 36 is a cross-sectional view of the structure of FIG. 34 electrically coupled to the structure of FIG. 35 to finish the fabrication of a wiring board in accordance with the third embodiment of the present invention;

FIG. 37 is a cross-sectional view of a semiconductor assembly with a semiconductor device, an electronic component and a lid mounted on the wiring board of FIG. 36 in accordance with the third embodiment of the present invention;

FIG. 38 is a cross-sectional view of another semiconductor assembly in accordance with the third embodiment of the present invention;

FIG. 39 is a cross-sectional view of yet another semiconductor assembly in accordance with the third embodiment of the present invention;

FIG. 40 is a cross-sectional view of another aspect of the wiring board in accordance with the third embodiment of the present invention;

FIG. 41 is a cross-sectional view of yet another aspect of the wiring board in accordance with the third embodiment of the present invention;

FIG. 42 is a cross-sectional view of yet another aspect of the wiring board in accordance with the third embodiment of the present invention;

FIGS. 43 and 44 are cross-sectional and top perspective views, respectively, of an interconnect element provided with a routing circuitry, a thermal pad and a bottom metal film in accordance with the fourth embodiment of the present invention;

FIGS. 45 and 46 are cross-sectional and top perspective views, respectively, of the structure of FIGS. 43 and 44 further provided with metal leads in accordance with the fourth embodiment of the present invention;

FIGS. 47 and 48 are cross-sectional and top perspective views, respectively, of the structure of FIGS. 45 and 46 further provided with a modified resin matrix in accordance with the fourth embodiment of the present invention;

FIGS. 49 and 50 are cross-sectional and top perspective views, respectively, of the structure of FIGS. 47 and 48 further provided with bridging elements to finish the fabrication of a wiring board in accordance with the fourth embodiment of the present invention;

FIGS. 51 and 52 are cross-sectional and top perspective views, respectively, of a semiconductor assembly with a semiconductor device and electronic components mounted on the wiring board of FIGS. 49 and 50 in accordance with the fourth embodiment of the present invention;

FIG. 53 is a cross-sectional view of another aspect of the wiring board in accordance with the fourth embodiment of the present invention;

FIG. 54 is a cross-sectional view of yet another aspect of the wiring board in accordance with the fourth embodiment of the present invention;

FIG. 55 is a cross-sectional view of an electrical isolator provided with a routing circuitry, a thermal pad, a bottom metal film and a metallized through via in accordance with the fifth embodiment of the present invention;

FIG. 56 is a cross-sectional view of the structure of FIG. 55 further provided with metal leads, a modified resin matrix and bridging elements to finish the fabrication of a wiring board in accordance with the fifth embodiment of the present invention;

FIG. 57 is a cross-sectional view of a semiconductor assembly with a semiconductor device and an electronic component mounted on the wiring board of FIG. 56 in accordance with the fifth embodiment of the present invention;

FIG. 58 is a cross-sectional view of another aspect of the wiring board in accordance with the fifth embodiment of the present invention; and

FIG. 59 is a cross-sectional view of yet another aspect of the wiring board in accordance with the fifth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that the accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

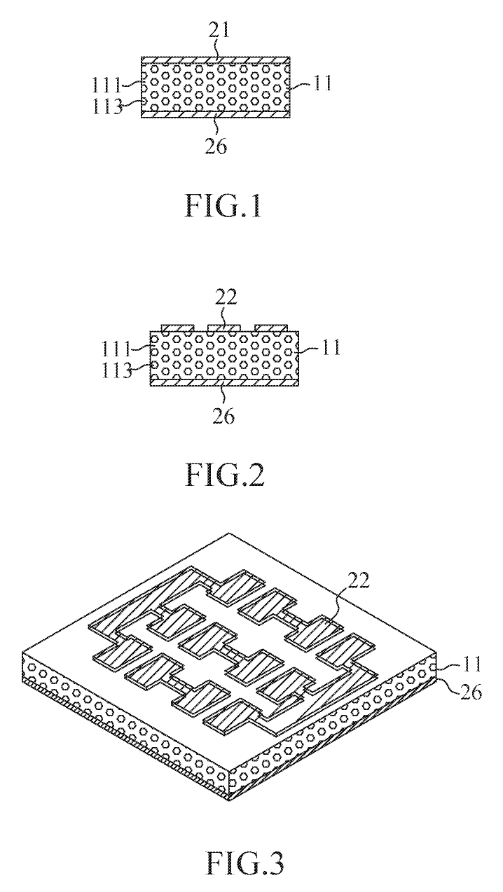

FIGS. 1-12 are schematic views showing a method of making a wiring board that includes an electrical isolator, a core substrate, a binding layer, a first routing circuitry, a second routing circuitry and bridging elements in accordance with the first embodiment of the present invention.

FIG. 1 is a cross-sectional view of the structure with a top metal film 21 and a bottom metal film 26 respectively deposited on planar top and bottom surfaces of an electrical isolator 11. In this embodiment, the electrical isolator 11 includes a resin adhesive 111 and a plurality of heat conducting elements 113 dispersed in the resin adhesive 111. The heat conducting elements 113 typically have a thermal conductivity of higher than 10 W/mk, preferably in an amount of about 10% by weight or more based on a total weight of the electric isolator 11. As a result, the electrical isolator 11 can serve as a thermally conductive and electrically insulating platform. The top metal film 21 and the bottom metal film 26 each have a planar exterior surface facing away from the electrical isolator 11, and are typically made of copper with a thickness of about 35 microns.

FIGS. 2 and 3 are cross-sectional and top perspective views, respectively, of the structure with a first routing circuitry 22 formed on the top surface of the electrical isolator 11 by metal patterning of the top metal film 21. The metal patterning techniques include wet etching, electro-chemical etching, laser-assist etching, and their combinations with an etch mask (not shown) thereon that defines the first routing circuitry 22. As shown in FIG. 3, the first routing circuitry 22 is a patterned metal layer and provides a plurality of contact pads for subsequent electrical connection.

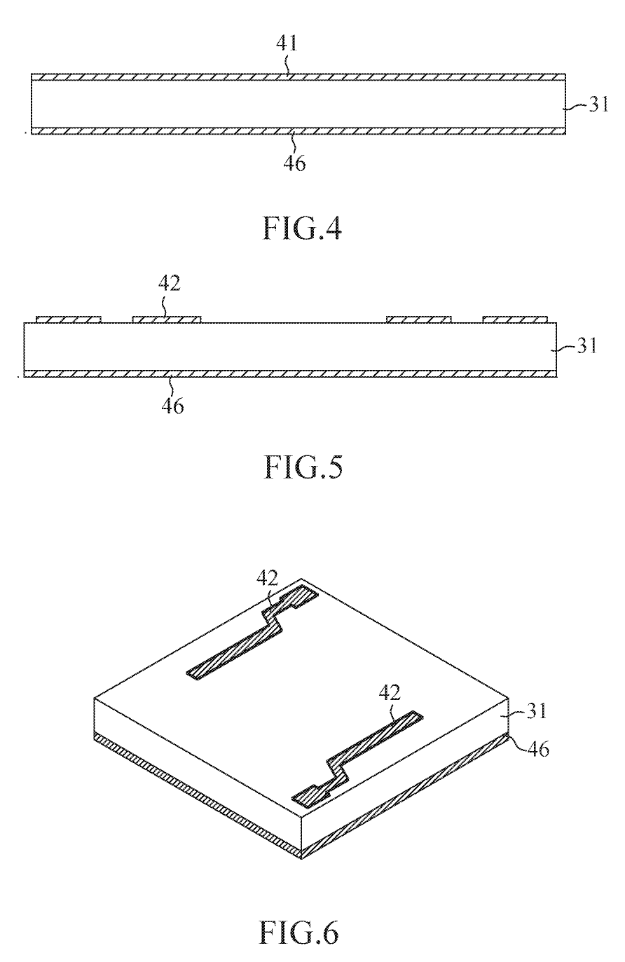

FIG. 4 is a cross-sectional view of the structure with a top metal layer 41 and a bottom metal layer 46 respectively deposited on planar top and bottom surfaces of a core substrate 31. The core substrate 31 may have a coefficient of thermal expansion different from that of the electrical isolator 11, and can be made of ceramic, glass, epoxy resin, molding compound, glass-epoxy, polyimide or the like. The top and bottom metal layers 41, 46 each have a planar exterior surface facing away from the core substrate 31, and typically are made of copper with a thickness of about 35 microns.

FIGS. 5 and 6 are cross-sectional and top perspective views, respectively, of the structure with a second routing circuitry 42 formed on the core substrate 31. By metal patterning of the top metal layer 41, the second routing circuitry 42 is formed on the top surface of the core substrate 31. As shown in FIG. 6, the second routing circuitry 42 is a patterned metal layer and provides a plurality of contact pads for subsequent electrical connection.

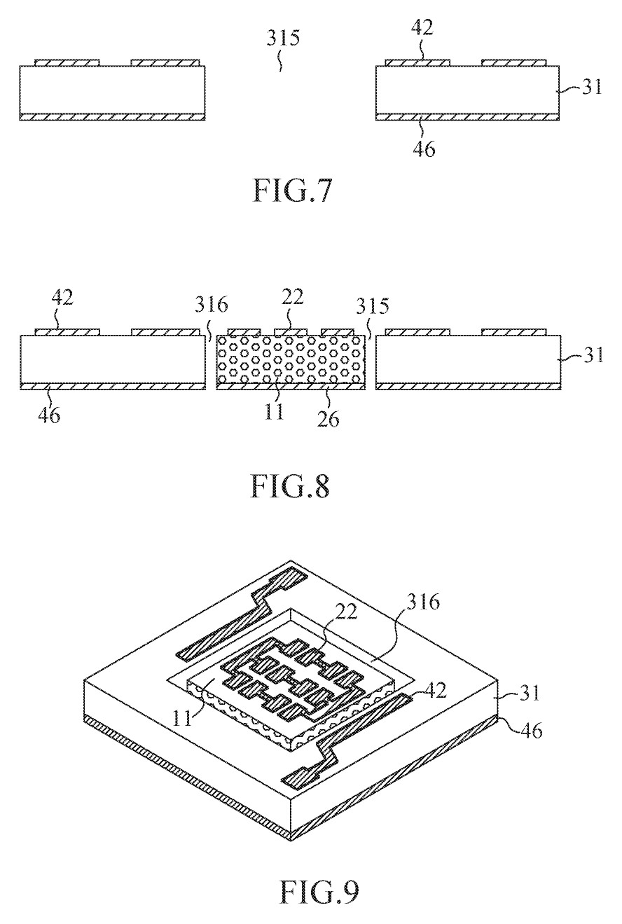

FIG. 7 is a cross-sectional view of the structure with an aperture 315 formed in the core substrate 31. The aperture 315 has interior sidewalls extending through the core substrate 31 between the top surface and the bottom surface thereof as well as the bottom metal layer 46. The aperture 315 can be formed by numerous techniques, such as punching or laser cutting.

FIGS. 8 and 9 are cross-sectional and top perspective views, respectively, of the structure with the electrical isolator 11 accommodated in the aperture 315 of the core substrate 31. The electrical isolator 11 is aligned with and inserted into the aperture 315 of the core substrate 31, with the exterior surfaces of the first routing circuitry 22 and the second routing circuitry 42 facing in the upward direction and substantially coplanar with each other. The interior sidewalls of the aperture 315 laterally surround and are spaced from peripheral sidewalls of the electrical isolator 11. As a result, a gap 316 is located in the aperture 315 between the peripheral sidewalls of the electrical isolator 11 and the interior sidewalls of the core substrate 31. The gap 316 laterally surrounds the electrical isolator 11 and is laterally surrounded by the core substrate 31.

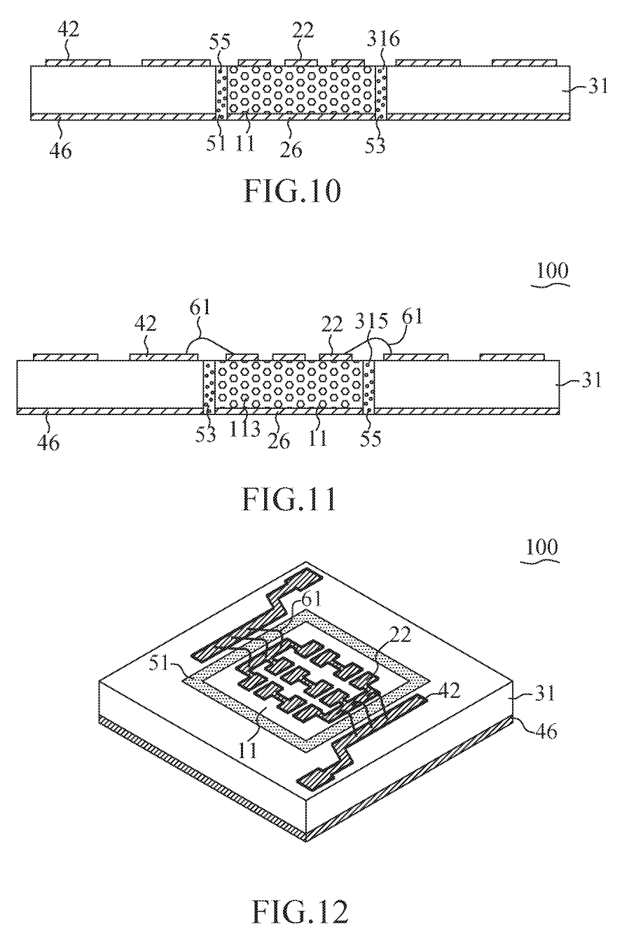

FIG. 10 is a cross-sectional view of the structure with a binding layer 53 dispensed in the gap 316. The binding layer 53, typically made of resin, fills in the gap 316 and laterally covers and surrounds and conformally coats the peripheral sidewalls of the electrical isolator 11 and the interior sidewalls of the core substrate 31. The binding layer 53 provides a secure robust mechanical bond between the electrical isolator 11 and the core substrate 31, and typically has a coefficient of thermal expansion (CTE) higher than those of the electrical isolator 11 and the core substrate 31. Optionally, a plurality of stress modulators 55, having lower CTE than that of the binding layer 53, may be dispersed in the binding layer 53 to form a modified binding matrix 51 in the gap 316 so as to effectively reduce the risk of resin cracking. Preferably, the CTE of the stress modulators 55 is lower by at least 10 ppm/° C. than that of the binding layer 53 so as to exhibit significant effect. In this embodiment, the modified binding matrix 51 contains the stress modulators 55 in an amount of at least 30% by volume based on the total volume of the gap 316, and preferably has a coefficient of thermal expansion of lower than 50 ppm/° C. As a result, the internal expansion and shrinkage of the modified binding matrix 51 during thermal cycling can be alleviated so as to restrain its cracking. Additionally, for effectively releasing thermo-mechanical induced stress, the modified binding matrix 51 preferably has a sufficient width of more than 10 micrometers (more preferably 25 micrometers or more) in the gap 316 to absorb the stress.

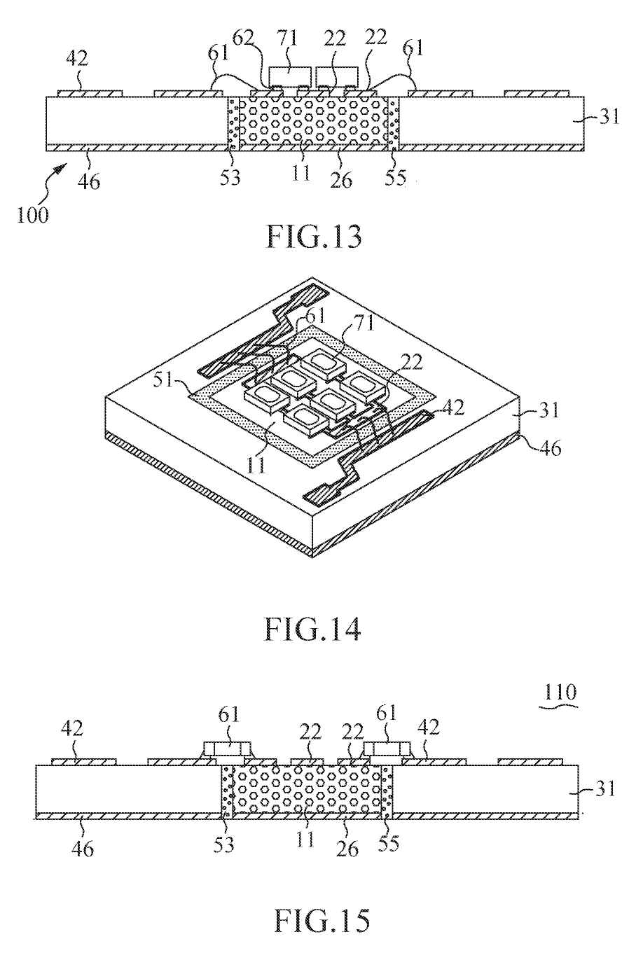

FIGS. 11 and 12 are cross-sectional and top perspective views, respectively, of the structure with bridging elements 61 in contact with the first routing circuitry 22 and the second routing circuitry 42. In this illustration, the bridging elements 61 are bonding wires, such as gold, copper or aluminum wires, and each are attached to and contact the first routing circuitry 22 on the electrical isolator 11 at one end thereof and to the second routing circuitry 42 on the core substrate 31 at another end thereof. As a result, the bridging elements 61 straddle over the interface between the adjoined top surfaces of the electrical isolator 11 and the core substrate 31 without any portion thereof being directly attached to the surfaces around the interface or the binding layer 53 in the interface to electrically connect the first routing circuitry 22 and the second routing circuitry 42.

Accordingly, as shown in FIGS. 11 and 12, a wiring board 100 is accomplished and includes the electrical isolator 11, the first routing circuitry 22, the bottom metal film 26, the core substrate 31, the second routing circuitry 42, the bottom metal layer 46, the binding layer 53, the stress modulators 55, and the bridging elements 61. The electrical isolator 11 is disposed in the aperture 315 of the core substrate 31 and includes the heat conducting elements 113 dispersed therein. The peripheral sidewalls of the electrical isolator 11 are attached to the interior sidewalls of the core substrate 31 by the binding layer 53 in contact with the peripheral sidewalls of the electrical isolator 11 and the interior sidewalls of the core substrate 31. The first routing circuitry 22 and the second routing circuitry 42 are patterned metal layers spaced apart from each other and deposited on the electrical isolator 11 and the core substrate 31, respectively. The bottom metal film 26 and the bottom metal layer 46 are unpatterned metal plates disposed underneath the electrical isolator 11 and the core substrate 31, respectively. The bridging elements 61 are attached to the first routing circuitry 22 and the second routing circuitry 42. As no portion of the bridging elements 61 is directly attached to the top surface of the electrical isolator 11, the top surface of the core substrate 31 or the binding layer 53 between the electrical isolator 11 and the core substrate 31, electrical disconnection caused by interfacial cracking can be avoided. In particular, by adding the stress modulators 55 in the binding layer 53, the risk of cracking induced by serious internal expansion and shrinkage of the binding layer 53 can be reduced, thereby ensuring the reliability of the wiring board 100.

FIGS. 13 and 14 are cross-sectional and top perspective views, respectively, of a semiconductor assembly with semiconductor devices 71 electrically connected to the wiring board 100 illustrated in FIGS. 11 and 12. The semiconductor devices 71, illustrated as LED chips, are flip-chip coupled to the first routing circuitry 22 on the electrical isolator 11 via bumps 62 in contact with the first routing circuitry 22. As a result, the semiconductor devices 71 are electrically connected to the second routing circuitry 42 on the core substrate 31 through the first routing circuitry 22 and the bridging elements 61.

FIG. 15 is a cross-sectional view of another aspect of the wiring board according to the first embodiment of the present invention. The wiring board 110 is similar to that illustrated in FIG. 11, except that the bridging elements 61 are illustrated as surface mounted devices. The surface mounted devices are adhered to the first routing circuitry 22 and the second routing circuitry 42 by soldering material in contact with the first routing circuitry 22 and the second routing circuitry 42.

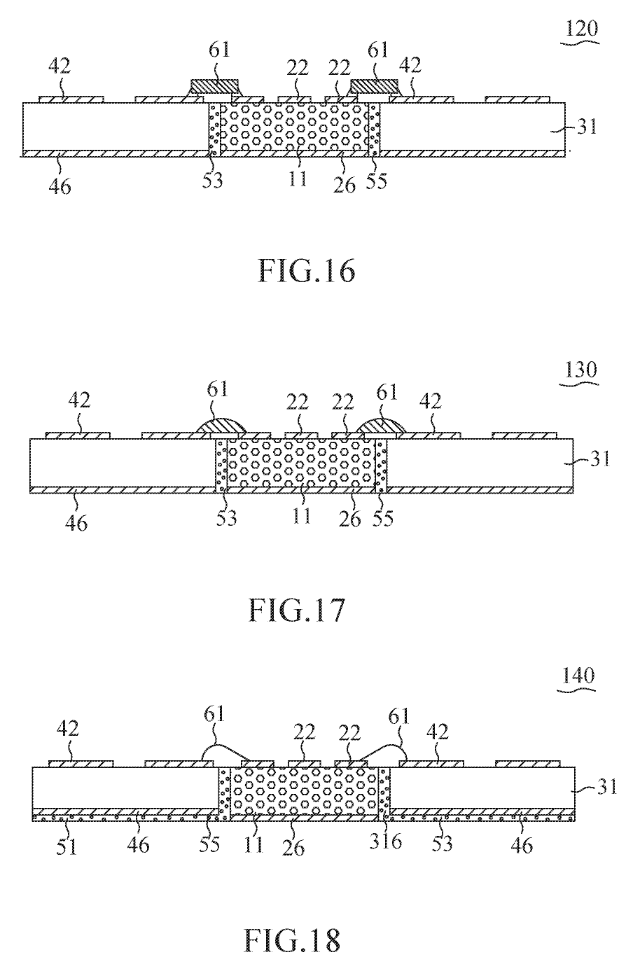

FIG. 16 is a cross-sectional view of yet another aspect of the wiring board according to the first embodiment of the present invention. The wiring board 120 is similar to that illustrated in FIG. 11, except that the bridging elements 61 are illustrated as metal plates. The metal plates are adhered to the first routing circuitry 22 and the second routing circuitry 42 by soldering material in contact with the first routing circuitry 22 and the second routing circuitry 42.

FIG. 17 is a cross-sectional view of yet another aspect of the wiring board according to the first embodiment of the present invention. The wiring board 130 is similar to that illustrated in FIG. 11, except that the bridging elements 61 are illustrated as soldering materials. The soldering materials contact the first routing circuitry 22 and the second routing circuitry 42 and span gaps between peripheral edges of the first routing circuitry 22 and the second routing circuitry 42.

FIG. 18 is a cross-sectional view of yet another aspect of the wiring board according to the first embodiment of the present invention. The wiring board 140 is similar to that illustrated in FIG. 11, except that the thickness of the core substrate 31 is less than that of the electrical isolator 11, and the modified binding matrix 51 extends outside of the gap 316 and further covers the bottom metal layer 46 underneath the core substrate 31. In this aspect, the modified binding matrix 51 contains the stress modulators 55 in an amount of at least 30% by volume based on the total volume of the modified binding matrix 51.

### Embodiment 2

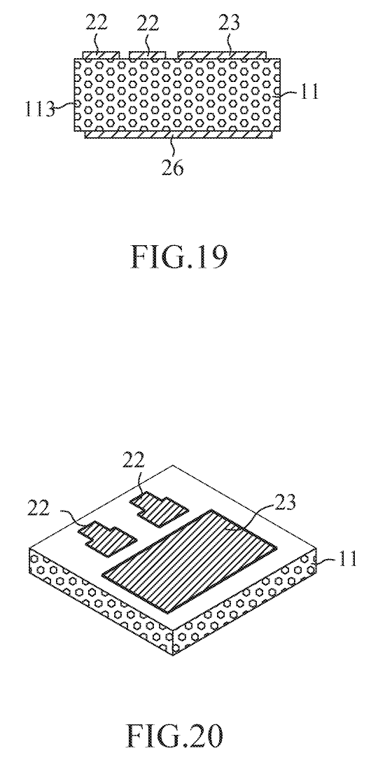

FIGS. 19-28 are schematic views showing a method of making another wiring board in accordance with the second embodiment of the present invention.

For purposes of brevity, any description in Embodiment 1 above is incorporated herein insofar as the same is applicable, and the same description need not be repeated.

FIGS. 19 and 20 are cross-sectional and top perspective views, respectively, of the structure having an electrical isolator 11 provided with a first routing circuitry 22 and a thermal pad 23 on its planar top surface and a bottom metal film 26 on its planar bottom surface. As shown in FIG. 20, the first routing circuitry 22 provides a plurality of contact pads for subsequent electrical connection, whereas the thermal pad 23 offers a highly thermally conductive plane for device attachment. The electrical isolator 11 includes heat conducting elements 113 dispersed therein. As a result, the first routing circuitry 22 and the thermal pad 23 are electrically isolated from and thermally conductible to the bottom metal film 26 by the electrical isolator 11 therebetween.

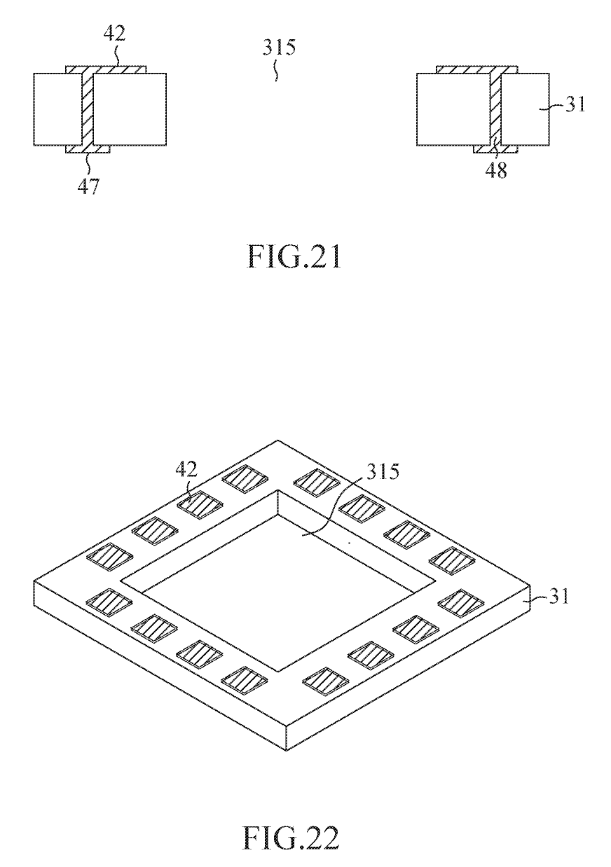

FIGS. 21 and 22 are cross-sectional and top perspective views, respectively, of the structure with a second routing circuitry 42 and a third routing circuitry 47 respectively deposited on planar top and bottom surfaces of a core substrate 31 and a metallized through holes 48 in the core substrate 31. The second routing circuitry 42 and the third routing circuitry 47 are patterned metal layers and electrically connected to each other through the metallized through holes 48 penetrating through the core substrate 31. The core substrate 31 has an aperture 315 extending from the top surface to the bottom surface thereof.

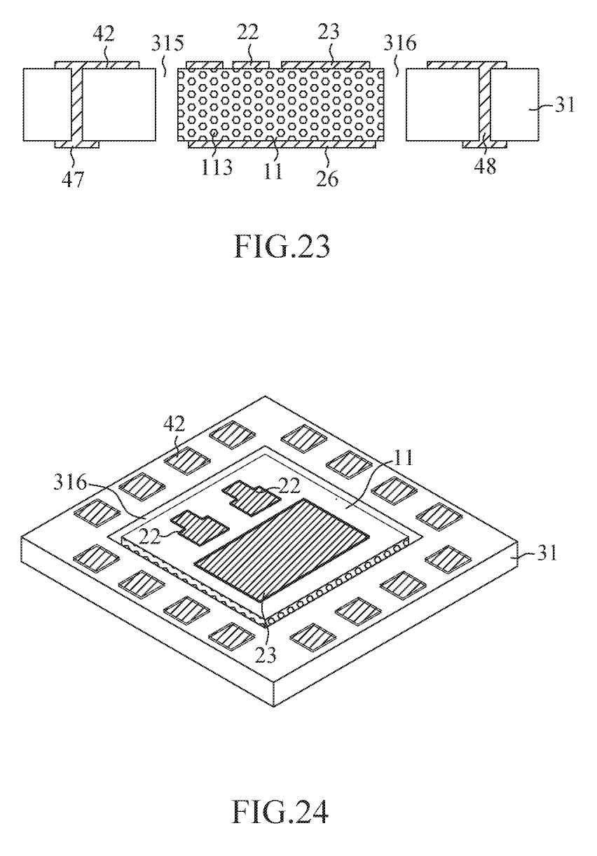

FIGS. 23 and 24 are cross-sectional and top perspective views, respectively, of the structure with the electrical isolator 11 accommodated in the aperture 315 of the core substrate 31. The peripheral sidewalls of the electrical isolator 11 are spaced from the interior sidewalls of the core substrate 31 by a gap 316 within the aperture 315.

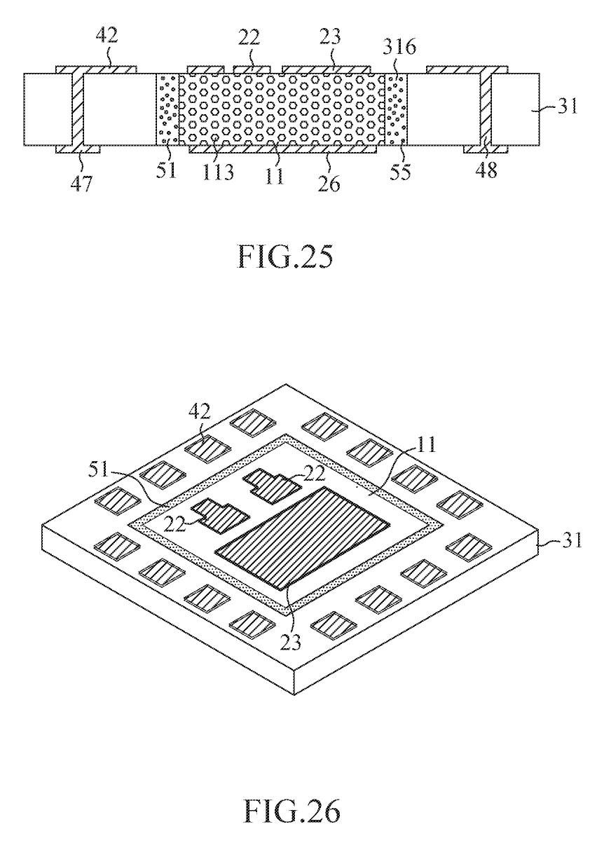

FIGS. 25 and 26 are cross-sectional and top perspective views, respectively, of the structure with a modified binding matrix 51 in the gap 316. The modified binding matrix 51 provides mechanical bonds between the electrical isolator 11 and the core substrate 31 and includes a plurality of stress modulators 55 dispersed therein.

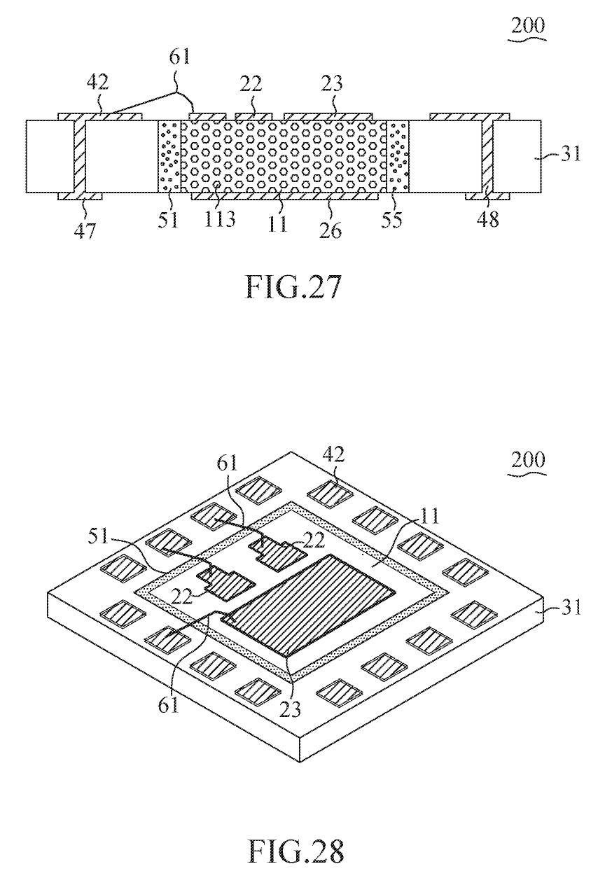

FIGS. 27 and 28 are cross-sectional and top perspective views, respectively, of a wiring board 200 with bonding wires used as bridging elements 61 for electrical connections between the first routing circuitry 22 and the second routing circuitry 42 and between the thermal pad 23 and the second routing circuitry 42. In this illustration, one of the bridging elements 61 is attached to the thermal pad 23 and the second routing circuitry 42, and the others are attached to the first routing circuitry 22 and the second routing circuitry 42. As the two routing circuitries (i.e. the first routing circuitry 22 and the second routing circuitry 42) on two adjoined surfaces are connected by the bridging elements 61 that straddle over the interfaces of the two adjoined surfaces, any cracking or delamination across the interfaces due to the mismatched CTE will not affect the routing integrity.

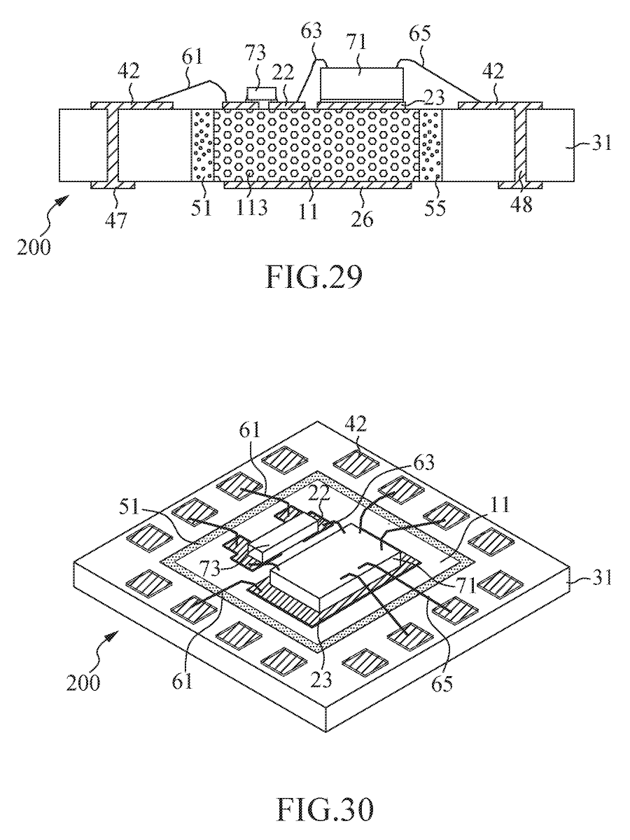

FIGS. 29 and 30 are cross-sectional and top perspective views, respectively, of a semiconductor assembly with a semiconductor device 71 and an electronic component 73 electrically connected to the wiring board 200 illustrated in FIGS. 27 and 28. The semiconductor device 71 is face-up mounted over the thermal pad 23 and electrically coupled to the first routing circuitry 22 through bonding wires 63 in contact with the first routing circuitry 22 and the semiconductor device 71 and to the second routing circuitry 42 through bonding wires 65 in contact with the second routing circuitry 42 and the semiconductor device 71. The electronic component 73 is attached to the first routing circuitry 22 and electrically connected to the second routing circuitry 42 through the first routing circuitry 22 and the bridging elements 61 and electrically connected to the semiconductor device 71 through the first routing circuitry 22 and the bonding wires 63. As a result, the semiconductor device 71 can be electrically connected to some contact pads of the second routing circuitry 42 through the bonding wires 65 and to others through the bonding wires 63, the first routing circuitry 22 and the bridging elements 61. The electronic component 73 may be a resistor, a capacitor, an inductor or any other passive or active component, so that the electrical characteristics of the semiconductor assembly can be improved.

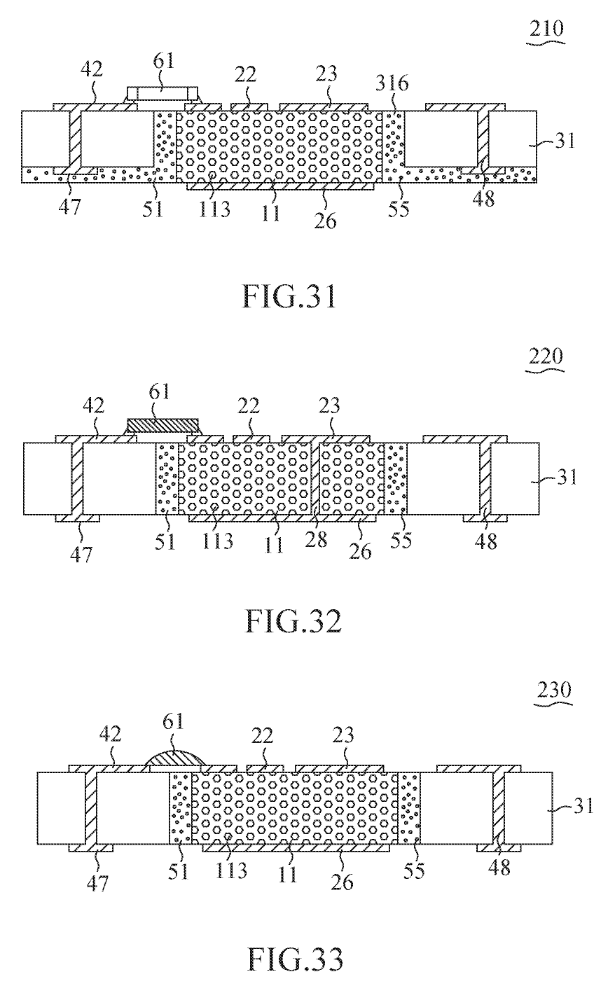

FIG. 31 is a cross-sectional view of another aspect of the wiring board according to the second embodiment of the present invention. The wiring board 210 is similar to that illustrated in FIG. 27, except that (i) the bridging elements 61 are illustrated as surface mounted devices, (ii) the core substrate 31 is thinner than the electrical isolator 11, and (iii) the modified binding matrix 51 extends outside of the gap 316 and further covers the bottom surface of the core substrate 31 as well as the third routing circuitry 47 underneath the core substrate 31.

FIG. 32 is a cross-sectional view of yet another aspect of the wiring board according to the second embodiment of the present invention. The wiring board 220 is similar to that illustrated in FIG. 27, except that it further includes a metallized through via 28 in the electrical isolator 11 and the bridging elements 61 are illustrated as metal plates. The metallized through via 28 penetrates through the electrical isolator 11, and has one end in contact with the thermal pad 23 and the other end in contact with the bottom metal film 26.

FIG. 33 is a cross-sectional view of yet another aspect of the wiring board according to the second embodiment of the present invention. The wiring board 230 is similar to that illustrated in FIG. 27, except that the bridging elements 61 are illustrated as soldering materials. The soldering materials contact the first routing circuitry 22 and the second routing circuitry 42 and span gaps between peripheral edges of the first routing circuitry 22 and the second routing circuitry 42.

### Embodiment 3

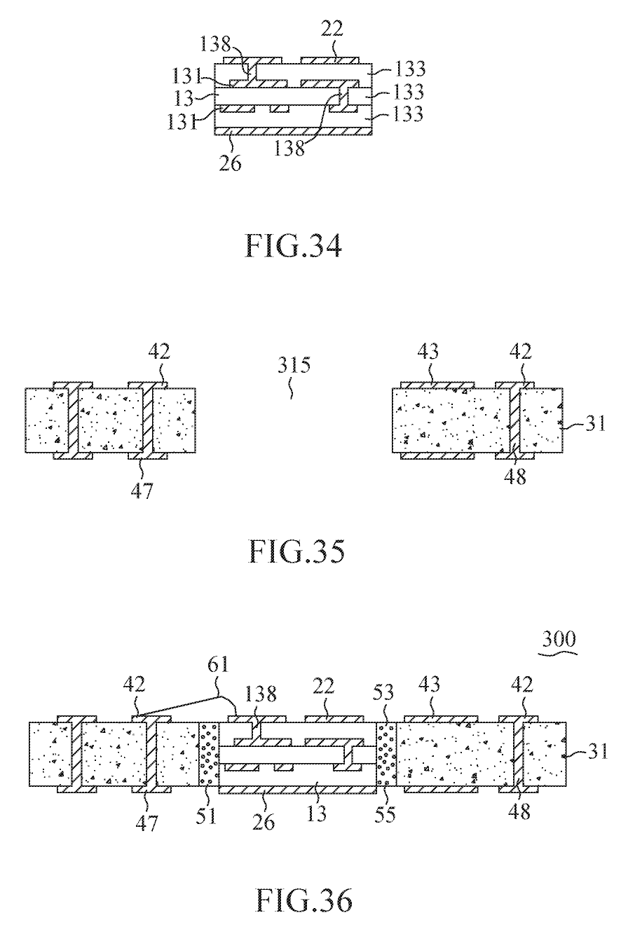

FIGS. 34-36 are schematic views showing a method of making yet another wiring board in accordance with the third embodiment of the present invention.

For purposes of brevity, any description in Embodiments above is incorporated herein insofar as the same is applicable, and the same description need not be repeated.

FIG. 34 is a cross-sectional view of the structure with a first routing circuitry 22 and a bottom metal film 26 respectively deposited on planar top and bottom surfaces of an interconnect element 13. In this embodiment, the interconnect element 13 is a resin-based multilayer wiring component and includes a plurality of circuitry layers 131 and a plurality of dielectric layers 133 formed in an alternate fashion. The first routing circuitry 22 laterally extends on the topmost dielectric layer 133 and is electrically coupled to the circuitry layers 131 through metal vias 138 in the dielectric layers 133, whereas the bottom metal film 26 laterally extends under the bottommost dielectric layer 133.

FIG. 35 is a cross-sectional view of the structure having a core substrate 31 provided with a second routing circuitry 42 and a thermal pad 43 on its planar top surface, a third routing circuitry 47 on its planar bottom surface and metallized through holes 48 embedded therein. The second routing circuitry 42 and the third routing circuitry 47 are electrically connected to each other through the metallized through holes 48 penetrating through the core substrate 31. The thermal pad 43 offers a highly thermally conductive plane for device attachment. The core substrate 31 may have a coefficient of thermal expansion different from that of the interconnect element 13 and includes an aperture 315 extending from the top surface to the bottom surface thereof.

FIG. 36 is a cross-sectional view of the structure with the interconnect element 13 bonded in an aperture 315 of the core substrate 31 through a modified binding matrix 51 and with bridging elements 61 in electrical connection with the first routing circuitry 22 and the second routing circuitry 42. The interconnect element 13 is aligned with and inserted into the aperture 315 of the core substrate 31, with the exterior surfaces of the first routing circuitry 22 and the second routing circuitry 42 facing in the upward direction and substantially coplanar with each other. In this embodiment, the modified binding matrix 51 includes a binding layer 53 filling in a gap between the peripheral sidewalls of the interconnect element 13 and the interior sidewalls of the core substrate 31 and a plurality of stress modulators 55 dispersed in the binding layer 53. The binding layer 53 provides secure robust mechanical bonds between the interconnect element 13 and the core substrate 31, and typically has a coefficient of thermal expansion (CTE) higher than those of the interconnect element 13 and the core substrate 31. The stress modulators 55 have lower CTE than that of the binding layer 53 to alleviate the internal expansion and shrinkage of the modified binding matrix 51. In this embodiment, the bridging elements 61 are illustrated as bonding wires attached to the first routing circuitry 22 at one end and to the second routing circuitry 42 at another end. As a result, the second routing circuitry 42 is electrically connected to the interconnect element 13 through the bridging elements 61, the first routing circuitry 22 and the metal vias 138.

At this stage, a wiring board 300 is accomplished and includes the interconnect element 13, the first routing circuitry 22, the bottom metal film 26, the core substrate 31, the second routing circuitry 42, the thermal pad 43, the third routing circuitry 47, the metallized through holes 48, the binding layer 53, the stress modulators 55 and the bridging elements 61.

FIG. 37 is a cross-sectional view of a semiconductor assembly with a semiconductor device 71 and an electronic component 73 electrically connected to the wiring board 300 illustrated in FIG. 36. The semiconductor device 71 is face-up mounted over the thermal pad 43 and electrically coupled to the first routing circuitry 22 through bonding wires 63 in contact with the first routing circuitry 22 and the semiconductor device 71 and to the second routing circuitry 42 through bonding wires 65 in contact with the second routing circuitry 42 and the semiconductor device 71. The electronic component 73 is attached to the first routing circuitry 22 and electrically connected to the second routing circuitry 42 through the first routing circuitry 22 and the bridging elements 61 and electrically connected to the semiconductor device 71 through the first routing circuitry 22 and the bonding wires 63. Further, a lid 81 is mounted on the wiring board 300 to enclose the semiconductor device 71 and electronic component 73 therein from above. In order to restrain the separation of the lid 91 from the core substrate 31 due to CTE mismatch, the core substrate 31 and the lid 91 preferably have the same CTE. In this embodiment, the core substrate 31 and the lid 91 are made of ceramic so as to prevent ambient moisture from getting into the interior of the semiconductor assembly.

FIG. 38 is a cross-sectional view of another aspect of the semiconductor assembly according to the third embodiment of the present invention. The wiring board 310 used in the semiconductor assembly is similar to that illustrated in FIG. 37, except that a plated layer 46 is further deposited under the bottom surface of the binding layer 53 and laterally extends under the bottom surface of the core substrate 31 to be integrated with the bottom metal film 26 and a selected portion of the third routing circuitry 47. As a result, the combination of the bottom metal film 26 and the plated layer 46 can serve as a sealing layer 96 that laterally extends under the bottom surface of the interconnect element 13, the bottom surface of the core substrate 31 and the bottom surface of the binding layer 53. In this aspect, the sealing layer 96 completely covers the bottom surface of the interconnect element 13 and the bottom surface of the binding layer 53 as well as the interfaces between the interconnect element 13 and the binding layer 53 and between the core substrate 31 and the binding layer 53 so as to prevent moisture from ambiance to enter through cracks at the interfaces into the interior of the semiconductor assembly.

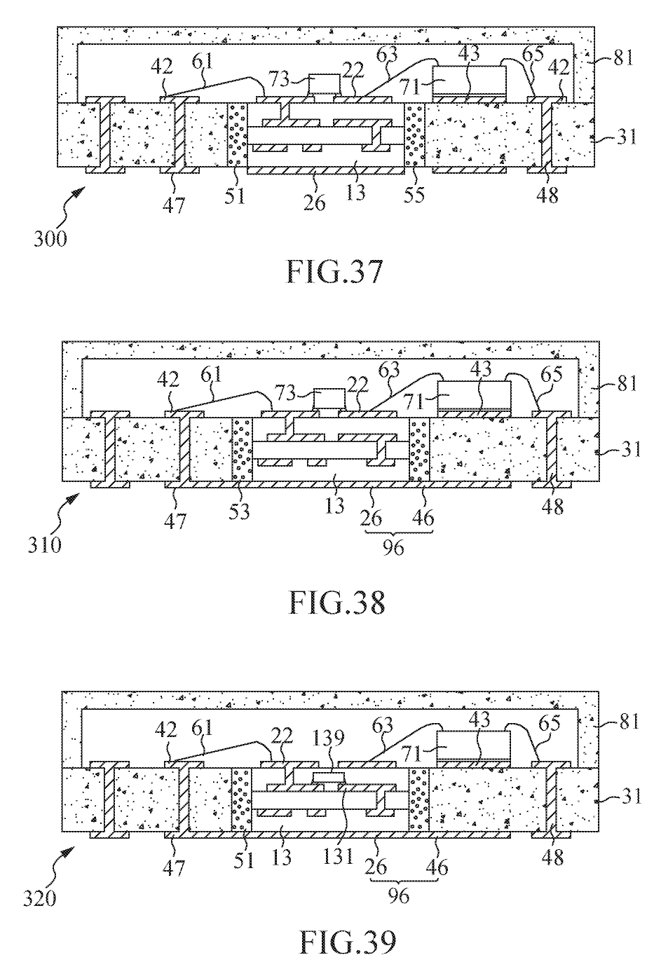

FIG. 39 is a cross-sectional view of yet another aspect of the semiconductor assembly according to the third embodiment of the present invention. The wiring board 320 used in the semiconductor assembly is similar to that illustrated in FIG. 38, except that the interconnect element 13 further includes an electronic component 139 embedded therein and electrically coupled to one of the circuitry layers 131. The electronic component 139 may be a resistor, a capacitor, an inductor or any other passive or active component. In this aspect, no electronic component is mounted over and electrically connected to the first routing circuitry 22.

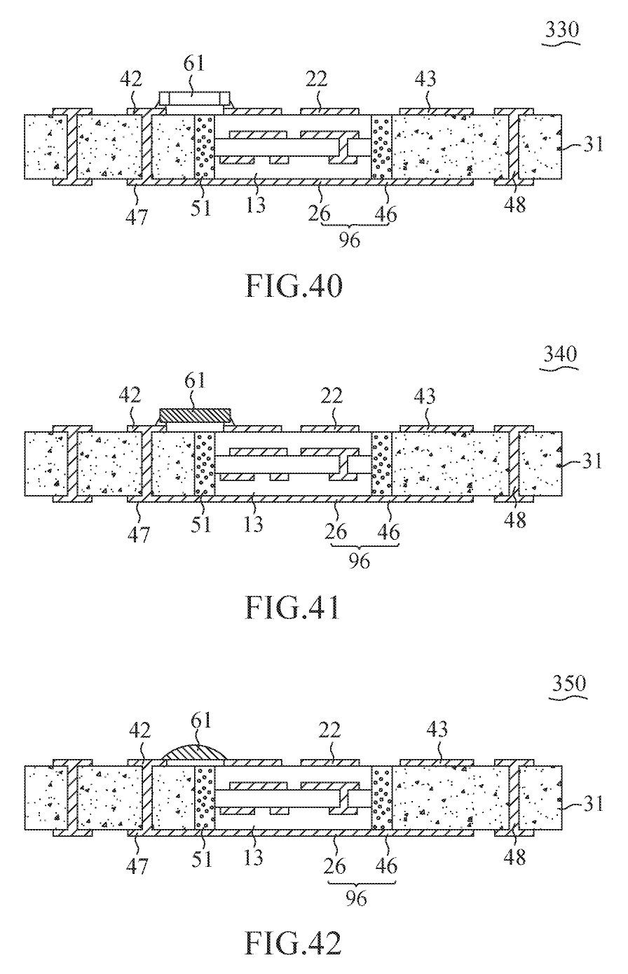

FIG. 40 is a cross-sectional view of yet another aspect of the wiring board according to the third embodiment of the present invention. The wiring board 330 is similar to that illustrated in FIG. 36, except that the bridging elements 61 are illustrated as surface mounted devices, and a plated layer 46 is further deposited under the bottom surface of the binding layer 53 and integrated with the bottom metal film 26 and a selected portion of the third routing circuitry 47.

FIG. 41 is a cross-sectional view of yet another aspect of the wiring board according to the third embodiment of the present invention. The wiring board 340 is similar to that illustrated in FIG. 40, except that the bridging elements 61 are illustrated as metal plates.

FIG. 42 is a cross-sectional view of yet another aspect of the wiring board according to the third embodiment of the present invention. The wiring board 350 is similar to that illustrated in FIG. 40, except that the bridging elements 61 are illustrated as soldering materials.

### Embodiment 4

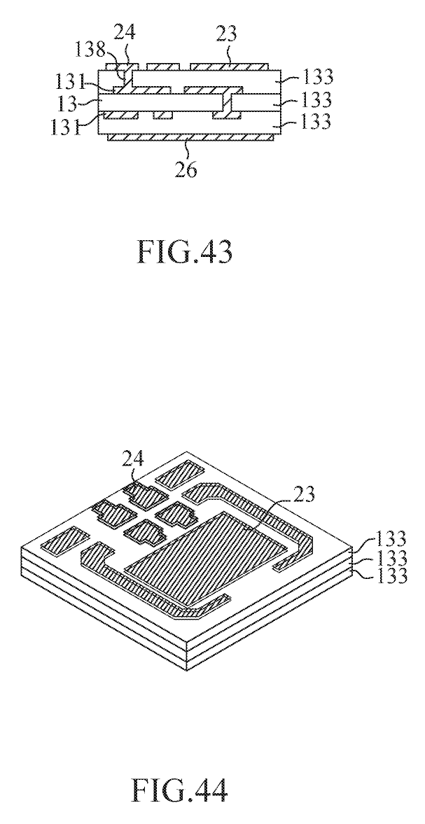

FIGS. 43-48 are schematic views showing a method of making yet another wiring board in accordance with the fourth embodiment of the present invention.

For purposes of brevity, any description in Embodiments above is incorporated herein insofar as the same is applicable, and the same description need not be repeated.

FIGS. 43 and 44 are cross-sectional and top perspective views, respectively, of the structure having an interconnect element 13 provided with a routing circuitry 24 and a thermal pad 23 on its planar top surface and a bottom metal film 26 on its planar bottom surface. The routing circuitry 24 and the thermal pad 23 are deposited on the topmost dielectric layer 133 of the interconnect element 13, whereas the bottom metal film 26 is deposited underneath the bottommost dielectric layer 133 of the interconnect element 13. Further, the routing circuitry 24 is electrically coupled to circuitry layers 131 through metal vias 138 of the interconnect element 13.

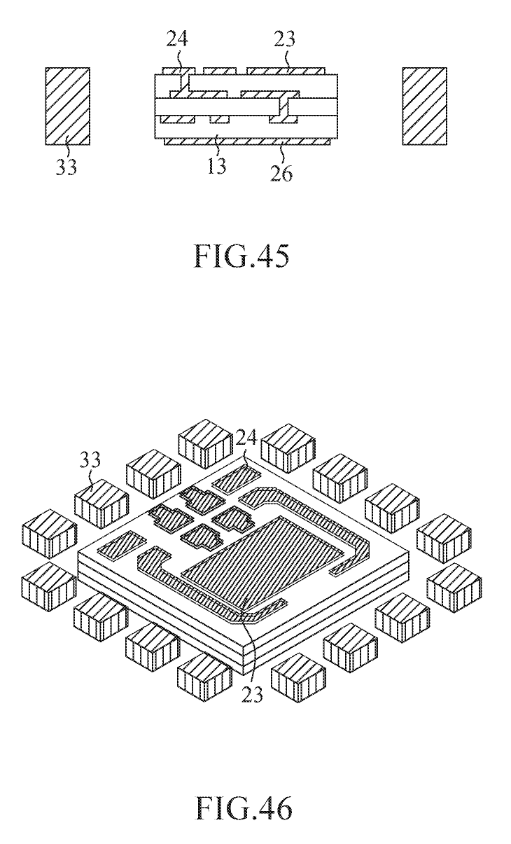

FIGS. 45 and 46 are cross-sectional and top perspective views, respectively, of the structure with a plurality of metal leads 33 about peripheral sidewalls of the interconnect element 13. The metal leads 33 are spaced from and laterally surround the peripheral sidewalls of the interconnect element 13, and each have a top side substantially coplanar with exterior surfaces of the routing circuitry 24 and the thermal pad 23 and a bottom side substantially coplanar with an exterior surface of the bottom metal film 26.

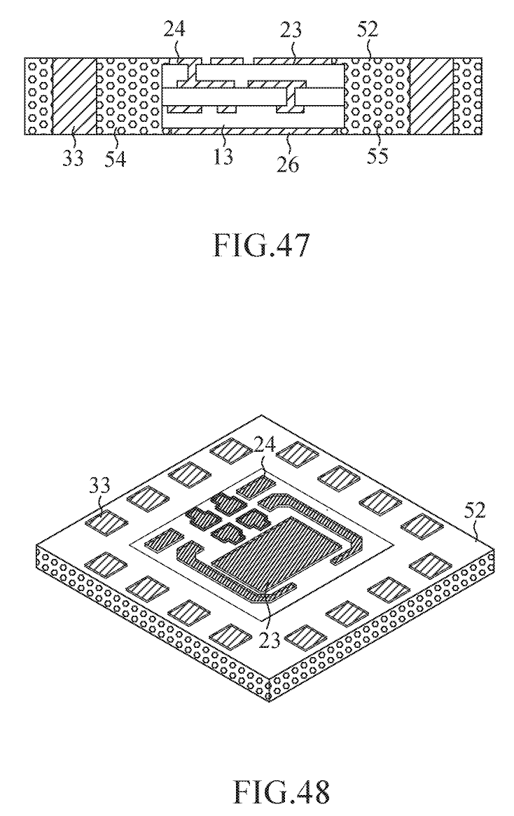

FIGS. 47 and 48 are cross-sectional and top perspective views, respectively, of the structure with a resin layer 54 deposited into the spaces between the metal leads 33 and bonded to the peripheral sidewalls of the interconnect element 13. The resin layer 54 laterally covers and surrounds and conformally coats the peripheral sidewalls of the interconnect element 13 and the metal leads 33. The resin layer 54 typically has a coefficient of thermal expansion (CTE) higher than those of the interconnect element 13 and the metal leads 33. In this illustration, the resin layer 54 has a top surface substantially coplanar with the exterior surfaces of the thermal pad 23 and the routing circuitry 24 and the top sides of the metal leads 33 and a bottom surface substantially coplanar with the exterior surface of the bottom metal film 26 and the bottom sides of the metal leads 33. Optionally, a plurality of stress modulators 55, having lower CTE than that of the resin layer 54, may be dispersed in the resin layer 54 to form a modified resin matrix 52 so as to effectively reduce the risk of resin cracking. Preferably, the CTE of the stress modulators 55 is lower by at least 10 ppm/° C. than that of the resin layer 54 so as to exhibit significant effect. In this embodiment, the modified resin matrix 52 contains the stress modulators 55 in an amount of at least 30% by volume based on the total volume of the modified resin matrix 52, and preferably has a coefficient of thermal expansion of lower than 50 ppm/C. As a result, the internal expansion and shrinkage of the modified resin matrix 52 during thermal cycling can be alleviated so as to restrain its cracking.

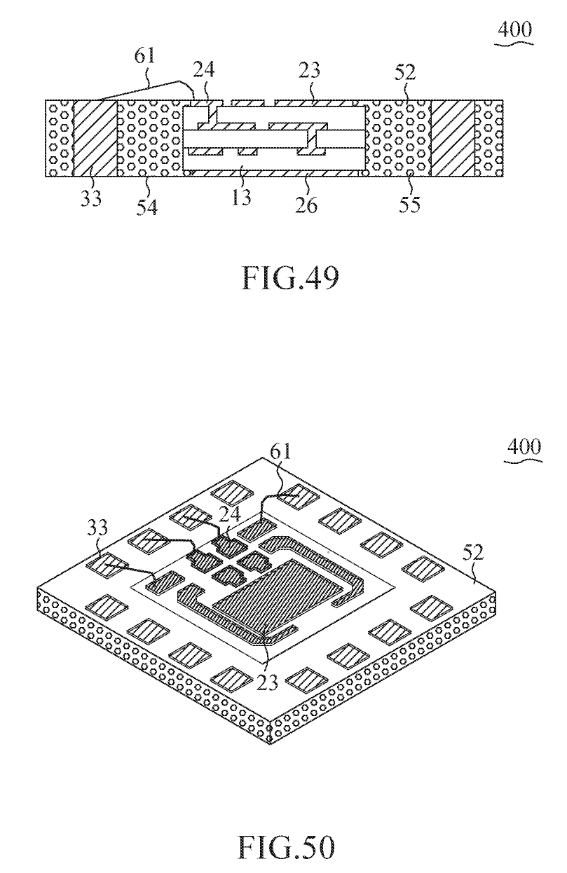

FIGS. 49 and 50 are cross-sectional and top perspective views, respectively, of the structure with bridging elements 61 in contact with the routing circuitry 24 and the metal leads 33. The bridging elements 61 are illustrated as bonding wires and attached to and contact the routing circuitry 24 on the interconnect element 13 at one end thereof and to the metal leads 33 at another end thereof. As a result, the bridging elements 61 straddle over the adjoined top surfaces of the interconnect element 13 and the metal leads 33 without direct attachment to the interfaces to electrically connect the routing circuitry 24 and the metal leads 33.

Accordingly, a wiring board 400 is accomplished and includes the interconnect element 13, the thermal pad 23, the routing circuitry 24, the bottom metal film 26, the metal leads 33, the resin layer 54, the stress modulators 55 and the bridging elements 61.

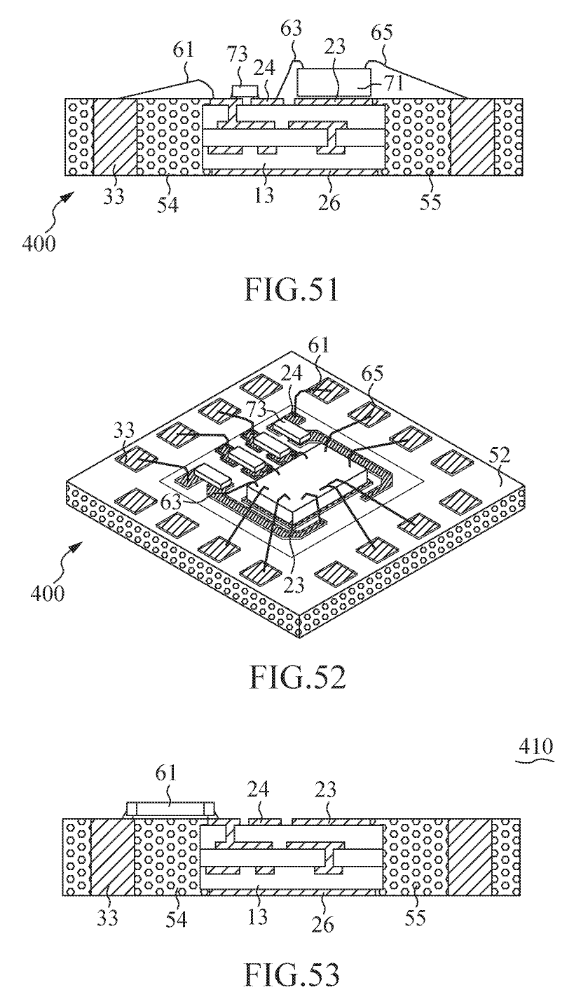

FIGS. 51 and 52 are cross-sectional and top perspective views, respectively, of a semiconductor assembly with a semiconductor device 71 and electronic components 73 electrically connected to the wiring board 400 illustrated in FIGS. 49 and 50. The semiconductor device 71 is face-up mounted over the thermal pad 23 and electrically coupled to the routing circuitry 24 through bonding wires 63 in contact with the routing circuitry 24 and the semiconductor device 71 and to the metal leads 33 through bonding wires 65 in contact with the metal leads 33 and the semiconductor device 71. The electronic components 73 are attached to the routing circuitry 24 and electrically connected to the metal leads 33 through the routing circuitry 24 and the bridging elements 61 and electrically connected to the semiconductor device 71 through the routing circuitry 24 and the bonding wires 63. As a result, the semiconductor device 71 can be electrically connected to some of the metal leads 33 through the bonding wires 65 and to others through the bonding wires 63, the routing circuitry 24 and the bridging elements 61.

FIG. 53 is a cross-sectional view of another aspect of the wiring board according to the fourth embodiment of the present invention. The wiring board 410 is similar to that illustrated in FIG. 49, except that the bridging elements 61 are illustrated as surface mounted devices. The surface mounted devices are adhered to the routing circuitry 24 and the metal leads 33 by soldering material in contact with the routing circuitry 24 and the metal leads 33.

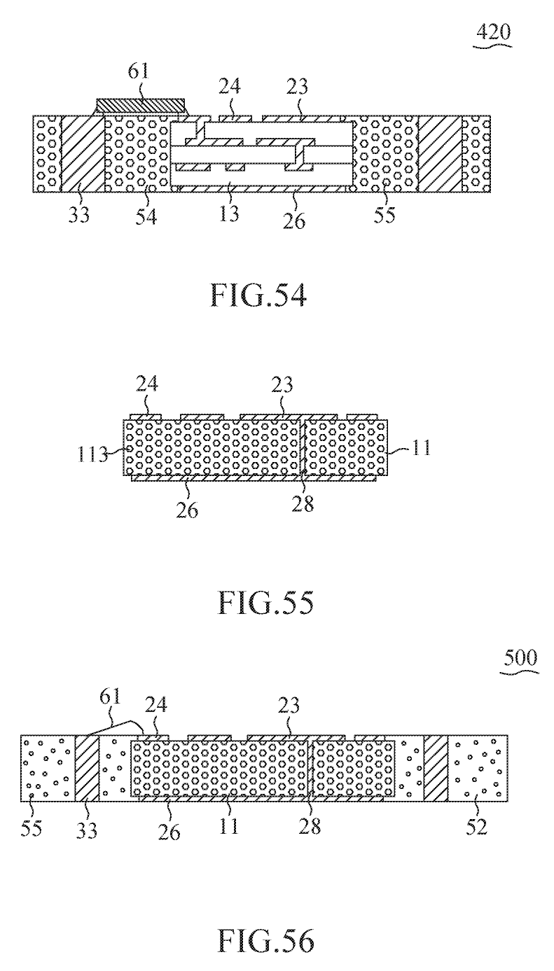

FIG. 54 is a cross-sectional view of yet another aspect of the wiring board according to the fourth embodiment of the present invention. The wiring board 420 is similar to that illustrated in FIG. 49, except that the bridging elements 61 are illustrated as metal plates that are adhered to the routing circuitry 24 and the metal leads 33 by soldering material in contact with the routing circuitry 24 and the metal leads 33.

### Embodiment 5

FIGS. 55-56 are schematic views showing a method of making yet another wiring board in accordance with the fifth embodiment of the present invention.

For purposes of brevity, any description in Embodiments above is incorporated herein insofar as the same is applicable, and the same description need not be repeated.

FIG. 55 is a cross-sectional view of the structure having an electrical isolator 11 provided with a routing circuitry 24 and a thermal pad 23 on its planar top surface, a bottom metal film 26 on its planar bottom surface, and a metal through via 28 in the electrical isolator 11. The electrical isolator 11 includes heat conducting elements 113 dispersed therein. The routing circuitry 24 provides a plurality of contact pads for subsequent electrical connection. The thermal pad 23 offers a highly thermally conductive plane for device attachment and is connected to the bottom metal film 26 through the metal through via 28.

FIG. 56 is a cross-sectional view of the structure with the electrical isolator 11 bonded with the metal leads 33 through a modified resin matrix 52 and electrically coupled to metal leads 33 through bridging elements 61. The metal leads 33 are spaced from and laterally surround the peripheral sidewalls of the electrical isolator 11. The modified resin matrix 52 laterally covers and surrounds and conformally coats the peripheral sidewalls of the electrical isolator 11 and the metal leads 33 and includes a plurality of stress modulators 55 dispersed therein. The bridging elements 61 are illustrated as bonding wires and attached to and contact the routing circuitry 24 on the electrical isolator 11 at one end thereof and to the metal leads 33 at another end thereof. As a result, the routing circuitry 24 is electrically connected to the metal leads 33 through the bridging elements 61 and the routing circuitry 24.

Accordingly, a wiring board 500 is accomplished and includes the electrical isolator 11, the thermal pad 23, the routing circuitry 24, the bottom metal film 26, the metallized through via 28, the metal leads 33, the modified resin matrix 52 and the bridging elements 61.

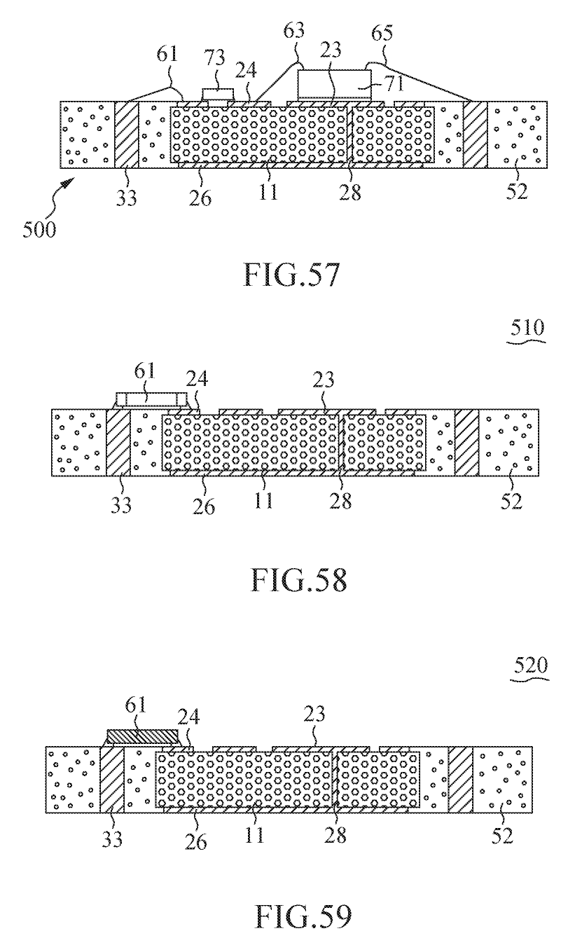

FIG. 57 is a cross-sectional view of a semiconductor assembly with a semiconductor device 71 and an electronic component 73 electrically connected to the wiring board 500 illustrated in FIG. 56. The semiconductor device 71 is face-up mounted over the thermal pad 23 and electrically coupled to the routing circuitry 24 through bonding wires 63 and to the metal leads 33 through bonding wires 65. The electronic component 73 are attached to the routing circuitry 24 and electrically connected to the metal leads 33 through the routing circuitry 24 and the bridging elements 61.

FIG. 58 is a cross-sectional view of another aspect of the wiring board according to the fifth embodiment of the present invention. The wiring board 510 is similar to that illustrated in FIG. 56, except that the bridging elements 61 are illustrated as surface mounted devices.

FIG. 59 is a cross-sectional view of yet another aspect of the wiring board according to the fifth embodiment of the present invention. The wiring board 520 is similar to that illustrated in FIG. 56, except that the bridging elements 61 are illustrated as metal plates.

As illustrated in the aforementioned embodiments, a distinctive wiring board is configured to exhibit improved reliability. In a preferred embodiment, a core substrate is bonded to and positioned about peripheral sidewalls of an electrical isolator or an interconnect element through a binding layer, and a first routing circuitry over the top surface of the electrical isolator or the interconnect element is electrically connected to a second routing circuitry over the top surface of the core substrate through one or more bridging elements. Alternatively, a plurality of metal leads may be disposed about and spaced from peripheral sidewalls of the electrical isolator or the interconnect element by a resin layer, and a routing circuitry over the top surface of the electrical isolator or the interconnect element is electrically connected to the top side of at least one of the metal leads through one or more bridging elements.

The electrical isolator includes a plurality of heat conducting elements dispensed therein for enhanced thermal dissipation and can serve as a platform for device attachment. For instance, the heat conducting elements may be dispersed in a resin adhesive by an amount of about 10% by weight or more. Preferably, the heat conducting elements have a thermal conductivity of higher than 10 W/mk. As a result, the electrical isolator can serve as an electrically insulating platform for circuitry deposited thereon and also provide primary heat conduction for the device so that the heat generated by the device can be conducted away.

The interconnect element may include a resin-based multilayer wiring component and optionally one or more electronic components (such as resistors, capacitors, inductors or any other passive or active components) embedded in and electrically coupled to the resin-based multilayer wiring component. More specifically, the interconnect element can include a plurality of circuitry layers electrically connected to one another through metal vias in dielectric layers so as to provide the wiring board with multilayer routing capability.

The core substrate surrounds peripheral sidewalls of the electrical isolator or the interconnect element and has interior sidewalls spaced from and attached to the peripheral sidewalls of the electrical isolator or the interconnect element by the binding layer. The core substrate may have a different CTE from that of the electrical isolator or the interconnect element. In a preferred embodiment, the core substrate is made of ceramic to prevent ambient moisture from getting into the interior of the semiconductor assembly.

The metal leads are positioned about the peripheral sidewalls of the electrical isolator or the interconnect element and typically have a different CTE from that of the electrical isolator or the interconnect element. The metal leads can serve as signal vertical transduction pathways and optionally provide ground/power plane for power delivery and return. Preferably, the metal leads have a top side substantially coplanar with the exterior surface of the routing circuitry on the electrical isolator or the interconnect element.

The binding layer laterally covers and surrounds and conformally coats the aperture sidewalls of the core substrate and the peripheral sidewalls of the electrical isolator/the interconnect element so as to provide secure robust mechanical bonds between the core substrate and the electrical isolator/the interconnect element. As the CTE of the binding layer typically is higher than those of other components in the wiring board (such as the electrical isolator, the interconnect element and the core substrate), it is prone to crack induced by internal expansion and shrinkage during thermal cycling. In order to reduce the risk of cracking, a plurality of stress modulators may be mixed and dispersed in the binding layer to form a modified binding matrix. The difference in CTE between the binding layer and the stress modulators may be 10 ppm/° C. or more so as to exhibit significant effect. Preferably, the stress modulators are in an amount of at least 30% (preferably 50% or more) by volume based on the total volume of the modified binding matrix, and the CTE of the modified binding matrix is lower than 50 ppm/C. As a result, the internal expansion and shrinkage of the modified binding matrix during thermal cycling can be alleviated so as to restrain its cracking. Furthermore, for effectively releasing thermo-mechanical induced stress, the modified binding matrix preferably has a sufficient width of more than 10 micrometers (more preferably 25 micrometers or more) in the gap to absorb the stress. Additionally, the modified binding matrix may extend outside of the gap and further cover the bottom surface of the core substrate.

The resin layer laterally covers and surrounds and conformally coats the peripheral sidewalls of the electrical isolator/interconnect element and the metal leads. As the CTE of the resin layer typically is higher than those of other components in the wiring board (such as the electrical isolator, the interconnect element and the metal leads), it is prone to crack induced by internal expansion and shrinkage during thermal cycling. In order to reduce the risk of resin cracking, a plurality of stress modulators may be mixed and dispersed in the resin layer to form a modified resin matrix. The difference in CTE between the resin layer and the stress modulators may be 10 ppm/° C. or more so as to exhibit significant effect. Preferably, the stress modulators are in an amount of at least 30% (preferably 50% or more) by volume based on the total volume of the modified resin matrix, and the CTE of the modified resin matrix is lower than 50 ppm/C. As a result, the internal expansion and shrinkage of the modified resin matrix during thermal cycling can be alleviated so as to restrain its cracking.

The first routing circuitry and the second routing circuitry are patterned metal layers formed on the top surface of the electrical isolator/the interconnect element and the top surface of the core substrate, respectively, before the step of attaching the electrical isolator/the interconnect element to the core substrate. Likewise, the routing circuitry is a patterned metal layer deposited on the top surface of the electrical isolator or the interconnect element before provision of the resin layer. In the aspects of using the interconnect element, the (first) routing circuitry is electrically connected to the interconnect element through metal vias in the dielectric layer of the interconnect element. The first routing circuitry on the electrical isolator or the interconnect element has peripheral edges spaced apart from those of the second routing circuitry on the core substrate. As a result, first routing circuitry on the electrical isolator or the interconnect element is electrically isolated from the second routing circuitry on the core substrate when no bridging element is attached to the first and second routing circuitries. Likewise, the routing circuitry on the electrical isolator or the interconnect element is electrically isolated from the metal leads when no bridging element is attached to the routing circuitry and the metal leads.

The bridging element is attached to the exterior surface of the first routing circuitry on the electrical isolator/interconnect element at one end and to the exterior surface of the second routing circuitry on the core substrate at another end, or is attached to the exterior surface of the routing circuitry on the electrical isolator/interconnect element at one end and to the top side of one of the metal leads at another side. As a result, the bridging element provides an electrical connection between the first routing circuitry on the electrical isolator/interconnect element and the second routing circuitry on the core substrate or between the routing circuitry on the electrical isolator/interconnect element and the metal leads. As the bridging elements straddle over the interfaces of two adjoined surfaces (i.e. the top surface of the electrical isolator/interconnect element and the top surface of the core substrate/metal lead) without any portion thereof being directly attached to the surfaces around the interfaces or the binding layer/resin layer in the interfaces, any cracking or delamination across the interfaces due to the mismatched CTE will not affect the routing integrity. The example of the bridging element includes, but is not limited to, a bonding wire, a surface mounted device (SMD), a metal plate, or a soldering material. For instance, the bonding wire can be electrically coupled to the first routing circuitry at one end and to the second routing circuitry at another end or electrically coupled to the routing circuitry at one end and to the metal lead at another end; the SMD or metal plate can be mounted on the exterior surfaces of the first and second routing circuitries or mounted on the exterior surface of the routing circuitry and the top side of the metal lead by soldering material; or the soldering material may be mounted across the gap between the first routing circuitry and the second routing circuitry and in contact with the first routing circuitry and the second routing circuitry.

The present invention also provides a semiconductor assembly that includes a semiconductor device such as chip electrically connected to the aforementioned wiring board using a wide variety of connection media including bumps (such as gold or solder bumps) or bonding wires. For instance, the semiconductor device may be flip-chip coupled to the first routing circuitry on the electrical isolator or on the interconnect element using bumps in contact with the first routing circuitry and thus electrically connected to the second routing circuitry on the core substrate through the first routing circuitry and the bridging element(s). Alternatively, the semiconductor device may be face-up mounted over the electrical isolator or the interconnect element and electrically coupled to the first routing circuitry using bonding wire(s) in contact with the first routing circuitry and the semiconductor device, and/or be electrically coupled to the second routing circuitry on the core substrate using additional bonding wire(s) in contact with the second routing circuitry and the semiconductor device. Likewise, in the aspect of using metal leads around the electrical isolator or the interconnect element, the semiconductor device may be face-up mounted over the electrical isolator or the interconnect element and coupled to the routing circuitry on electrical isolator or the interconnect element using bonding wire(s) in contact with the routing circuitry and the semiconductor device, and/or be electrically coupled to the metal lead(s) using additional bonding wire(s) in contact with the metal lead(s) and the semiconductor device. As a result, the semiconductor device can be electrically connected to the second routing circuitry or the metal lead(s) through the bonding wire(s), the (first) routing circuitry and the bridging element(s) or/and directly through the additional bonding wire(s). In accordance with certain embodiments, the semiconductor device may be mounted over the core substrate and electrically connected to the first routing circuitry. For instance, the semiconductor device may be face-up attached over the core substrate and electrically coupled to the first routing circuitry on the interconnect element using bonding wire(s) in contact with the semiconductor device and the first routing circuitry, and/or electrically coupled to the second routing circuitry on the core substrate using additional bonding wire(s) in contact with the semiconductor device and the second routing circuitry. As a result, the semiconductor device can be electrically connected to the second routing circuitry through the bonding wire(s), the first routing circuitry and the bridging element(s) or/and directly through the additional bonding wire(s). Additionally, the semiconductor assembly may further include one or more electronic components (such as resistors, capacitors, inductors or any other passive or active components) mounted over the (first) routing circuitry on the electrical isolator or on the interconnect element so as to improve the electrical characteristics of the assembly. In accordance with certain embodiments, the electronic component may be electrically connected to the second routing circuitry on the core substrate or to the metal lead(s) through the (first) routing circuitry and the bridging element(s) and electrically connected to the semiconductor device through the (first) routing circuitry and bonding wire(s) in contact with the semiconductor device and the (first) routing circuitry. Further, the semiconductor assembly may further include a lid mounted over the top surface of the core substrate to enclose the semiconductor device and the optional electronic component(s) therein. Preferably, the core substrate and the lid are made of ceramic so as to prevent ambient moisture from getting into the interior of the semiconductor assembly. Moreover, the wiring board may further include a sealing layer (typically a metal layer) that laterally extends under the bottom surface of the interconnect element, the bottom surface of the core substrate and the bottom surface of the binding layer. Preferably, the sealing layer completely covers the bottom surface of the binding layer and the bottom surface of the interconnect element as well as the interfaces between the interconnect element and the binding layer and between the core substrate and the binding layer so as to prevent moisture through cracks at the interfaces from ambiance into the interior of the semiconductor assembly.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The chip can be a packaged or unpackaged chip. Furthermore, the chip can be a bare chip, or a wafer level packaged die, etc.

The term “cover” refers to incomplete or complete coverage in a vertical and/or lateral direction. For instance, in a preferred embodiment, the binding layer further covers the bottom surface of the core substrate regardless of whether another element such as the bottom metal layer is between the binding layer and the core substrate.

The term “surround” refers to relative position between elements regardless of whether the elements are spaced from or adjacent to one another. For instance, in a preferred embodiment, the metal leads laterally surround the electrical isolator or the interconnect element and are spaced from the electrical isolator or the interconnect element by the resin layer.

The phrases “mounted on/over” and “attached on/over” include contact and non-contact with a single or multiple support element(s). For instance, in a preferred embodiment, the semiconductor device can be attached on the core substrate regardless of whether it contacts the core substrate or separated from the core substrate by a thermal pad.

The phrases “electrical connection”, “electrically connected” and “electrically coupled” refer to direct and indirect electrical connection. For instance, in a preferred embodiment, the first routing circuitry is electrically connected to the second routing circuitry by the bridging elements but does not contact the second routing circuitry.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A wiring board, comprising:
a core substrate having an aperture, wherein interior sidewalls of the aperture extend through the core substrate between a top surface and a bottom surface thereof;
an electrical isolator disposed in the aperture of the core substrate, wherein the electrical isolator includes a plurality of heat conducting elements dispensed therein;
a binding layer that fills a gap between peripheral sidewalls of the electrical isolator and the interior sidewalls of the aperture, wherein the binding layer has a coefficient of thermal expansion different from those of the electrical isolator and the core substrate;
a first routing circuitry disposed on a top surface of the electrical isolator and a second routing circuitry disposed on the top surface of the core substrate, wherein the first routing circuitry and the second routing circuitry are substantially coplanar at exterior surfaces thereof and spaced apart from each other; and
a bridging element that is attached to the first routing circuitry at one end and to the second routing circuitry at another end to electrically connect the first routing circuitry and the second routing circuitry, wherein no portion of the bridging element is directly attached to the top surface of the electrical isolator, the top surface of the core substrate or the binding layer between the electrical isolator and the core substrate.

2. The wiring board of claim 1, wherein the thermal conductivity of the heat conducting elements is higher than 10 W/mk.

3. The wiring board of claim 1, further comprising a plurality of stress modulators dispensed in the binding layer to form a modified binding matrix having a width of more than 10 micrometers in the gap, wherein the stress modulators have a coefficient of thermal expansion lower than that of the binding layer, and the modified binding matrix has a coefficient of thermal expansion lower than 50 ppm/° C.

4. The wiring board of claim 1, wherein the bridging element is a bonding wire that includes gold, copper or aluminum wire.

5. The wiring board of claim 1, wherein the bridging element is a surface mounted device or a metal plate, and the bridging element is attached to the first and second routing circuitries by a soldering material.

6. The wiring board of claim 1, wherein the bridging element is a soldering material that contacts the first routing circuitry and the second routing circuitry directly.

7. A wiring board, comprising:
a core substrate having an aperture, wherein interior sidewalls of the aperture extend through the core substrate between a top surface and a bottom surface thereof;
an interconnect element disposed in the aperture of the core substrate, wherein the interconnect element includes a plurality of circuitry layers and a plurality of dielectric layers in an alternate fashion;
a binding layer that fills a gap between peripheral sidewalls of the interconnect element and the interior sidewalls of the aperture, wherein the binding layer has a coefficient of thermal expansion different from those of the interconnect element and the core substrate;
a first routing circuitry disposed on a top surface of the interconnect element and a second routing circuitry disposed on the top surface of the core substrate, wherein the first routing circuitry is electrically coupled to the circuitry layers of the interconnect element, and the first routing circuitry and the second routing circuitry are substantially coplanar at exterior surfaces thereof and spaced apart from each other; and
a bridging element that is attached to the first routing circuitry at one end and to the second routing circuitry at another end to electrically connect the first routing circuitry and the second routing circuitry, wherein no portion of the bridging element is directly attached to the top surface of the interconnect element, the top surface of the core substrate or the binding layer between the interconnect element and the core substrate.

8. The wiring board of claim 7, further comprising a plurality of stress modulators dispensed in the binding layer to form a modified binding matrix having a width of more than 10 micrometers in the gap, wherein the stress modulators have a coefficient of thermal expansion lower than that of the binding layer, and the modified binding matrix has a coefficient of thermal expansion lower than 50 ppm/° C.

9. The wiring board of claim 7, wherein the bridging element is a bonding wire that includes gold, copper or aluminum wire.

10. The wiring board of claim 7, wherein the bridging element is a surface mounted device or a metal plate, and the bridging element is attached to the first and second routing circuitries by a soldering material.

11. The wiring board of claim 7, wherein the interconnect element includes a resin-based multilayer wiring component having the plurality of circuitry layers and the plurality of dielectric layers.

12. The wiring board of claim 7, further comprising a sealing layer that laterally extends under a bottom surface of the interconnect element, the bottom surface of the core substrate and a bottom surface of the binding layer.

13. A wiring board, comprising:
an interconnect element including a plurality of circuitry layers and a plurality of dielectric layers in an alternate fashion;
a plurality of metal leads that laterally surround peripheral sidewalls of the interconnect element;
a resin layer that fills spaces between the metal leads and surrounds the peripheral sidewalls of the interconnect element, wherein the resin layer has a coefficient of thermal expansion different from those of the interconnect element and the metal leads;
a routing circuitry disposed on a top surface of the interconnect element, wherein the routing circuitry is electrically coupled to the circuitry layers of the interconnect element, and the routing circuitry has an exterior surface substantially coplanar with top sides of the metal leads and is spaced apart from the metal leads; and
a bridging element that is attached to routing circuitry at one end and to the plurality of metal leads at another end to electrically connect the routing circuitry and the plurality of metal leads, wherein no portion of the bridging element is directly attached to the top surface of the interconnect element or a top surface of the resin layer.

14. The wiring board of claim 13, further comprising a plurality of stress modulators dispensed in the resin layer to form a modified resin matrix, wherein the stress modulators have a coefficient of thermal expansion lower than that of the resin layer, and the modified resin matrix has a coefficient of thermal expansion lower than 50 ppm/C.

15. The wiring board of claim 13, wherein the bridging element is a bonding wire that includes gold, copper or aluminum wire.

16. The wiring board of claim 13, wherein the bridging element is a surface mounted device or a metal plate, and the bridging element is attached to the routing circuitry and the plurality of metal leads by a soldering material.

17. The wiring board of claim 13, wherein the interconnect element includes a resin-based multilayer wiring component having the plurality of circuitry layers and the plurality of dielectric layers.

18. A wiring board, comprising:
an electrical isolator including a plurality of heat conducting elements dispensed therein;
a plurality of metal leads that laterally surround peripheral sidewalls of the electrical isolator;
a resin layer that fills spaces between the metal leads and surrounds the peripheral sidewalls of the electrical isolator, wherein the resin layer has a coefficient of thermal expansion different from those of the electrical isolator and the metal leads;
a routing circuitry disposed on a top surface of the electrical isolator, wherein the routing circuitry has an exterior surface substantially coplanar with top sides of the metal leads and is spaced apart from the metal leads; and
a bridging element that is attached to routing circuitry at one end and to the plurality of metal leads at another end to electrically connect the routing circuitry and the plurality of metal leads, wherein no portion of the bridging element is directly attached to the top surface of the electrical isolator or a top surface of the resin layer.

19. The wiring board of claim 18, wherein a thermal conductivity of the heat conducting elements is higher than 10 W/mk.

20. The wiring board of claim 18, further comprising a plurality of stress modulators dispensed in the resin layer to form a modified resin matrix, wherein the stress modulators have a coefficient of thermal expansion lower than that of the resin layer, and the modified resin matrix has a coefficient of thermal expansion lower than 50 ppm/° C.

21. The wiring board of claim 18, wherein the bridging element is a bonding wire that includes gold, copper or aluminum wire.

22. The wiring board of claim 18, wherein the bridging element is a surface mounted device or a metal plate, and the bridging element is attached to the routing circuitry and the plurality of metal leads by a soldering material.
